(19) United States
(12) Patent Application Publication
(10) Pub. No.: US 2014/0294119 A1
(43) Pub. Date: Oct. 2, 2014

(54) System and Method for Distortion-Power Adapted Adaptive Pre-Distortion

(71) Applicant: Comtech EF Data Corp., Tempe, AZ (US)

(72) Inventor: John Sochacki, Gilbert, AZ (US)

(21) Appl. No.: 14/304,226

(22) Filed: Jun. 13, 2014

Related U.S. Application Data
(60) Provisional application No. 61/834,652, filed on Jun. 13, 2013.

(51) Int. Cl. H04B 1/62; H03F 1/32

(52) U.S. Cl. CPC H04B 1/62; H03F 1/3258; H04B 2001/0425
USPC 375/296

(57) ABSTRACT

A method of generating N^{th} order product predistortion coefficients for use by a linearizer in a non-linear communications system comprising receiving an input signal by a processor, applying, by the processor, a frequency domain-based adaptation algorithm by measuring N^{th} order products of an output signal of the system and iteratively adjusting a predistortion coefficient of a predistorter until the N^{th} order product is substantially equal to a predetermined minimum value.

### CROSS REFERENCE TO RELATED APPLICATIONS

This document claims the benefit of the filing date of U.S. Provisional Patent Application No. 61/834,652, entitled “System and Method for N-th Order Product Pre-Distortion Coefficient Generation For Use With Polynomial Based Waveform Digital Predistortion Linearizer” to John Sochacki, which was filed on Jun. 13, 2013, the disclosure of which is hereby incorporated entirely by reference herein.

### BACKGROUND

1. Technical Field

Aspects of this document relate generally to telecommunication systems and techniques for transmitting data across a telecommunication channel.

2. Background Art

In the prior art, digital predistortion (DPD) or adaptive analog predistortion (AAPD) systems require the use of additional proprietary equipment to accommodate wideband feedback when using processing and microwave equipment that is not collocated. In conventional systems, the necessary proprietary hardware and software may be installed or integrated with the microwave equipment as this is one of the two locations in the communication system through which all outbound and inbound signals must travel; however this approach has significant limitations due to the amount of bandwidth that must be processed as well as the high cost of components needed to perform DPD and AAPD when these components are rated to operate in the same environment as microwave equipment. Additionally, this approach may also result in in an increase in the size of the microwave equipment which may be disadvantageous, and the hardware used to perform the DPD and AAPD also has the potential to result in signal integrity issues when placed in close proximity to the microwave equipment.

Alternatively, another existing solution is to add a proprietary interface to enable DPD or AAPD in installations in which all or most of the equipment is from a single manufacturer. One of the drawbacks of this approach, however, is that this presents a significant limitation on interoperability of the system due to the requirement that old equipment is replaced with newer equipment that has been designed to work with the proprietary interface thereby also increasing overall costs.

### SUMMARY

Implementations of a method of generating N^{th} order product predistortion coefficients for use by a linearizer in a non-linear communications system may comprise receiving an input signal by a processor, applying, by the processor, a frequency domain-based adaptation algorithm by measuring N^{th} order products of an output signal of the system and iteratively adjusting a predistortion coefficient of a predistorter until an N^{th} order product output of the processor is substantially equal to a predetermined value.

Particular aspects may comprise one or more of the following features. The method may further comprise iteratively adjusting a phase of the predistorter until the N^{th} order product output of the system is substantially equal to a predetermined minimum value. The predetermined value may be substantially equal to an N^{th} order product output of the system. The method may further comprise sampling and isolating the input signal prior to predistortion using the processor, downconverting the sample using a downconverter, determining a power level of the sample, and transmitting the power level of the sample to a transmitter. The sampling, downconverting, and determining may occur within hardware integrated into the transmitter. The sampling, downconverting, and determining may occur external to the transmitter. The method may further comprise transmitting feedback information within a transmission overhead bandwidth of the output signal. The method may further comprise transmitting feedback information using low-speed auxiliary signaling. The downconverting may be such that any portion of or frequency of the signal may be sampled by a single filtering and power detection device. The method may further comprise sweeping a phase of the predistorter from 0 to 359 degrees.

Implementations of a system for generating N^{th} order product predistortion coefficients for use by a linearizer in a non-linear communications system may comprise a processor configured to receive an input signal and apply a frequency domain-based adaptation algorithm by measuring N^{th} order products of an output signal of the system and iteratively adjusting a predistortion coefficient of a predistorter until an N^{th} order product output of the processor is substantially equal to a predetermined value.

Particular aspects may comprise one or more of the following features. The processor may be further configured to iteratively adjust a phase of the predistorter until the N^{th} order product output of the system is substantially equal to a predetermined minimum value. The predetermined value may be substantially equal to an N^{th} order product output of the system. The processor may be further configured to sample and isolate the input signal prior to predistortion and determine a power level of the sample and the system may further comprise a downconverter configured to downconvert the sample and a transmitter configured to receive the power level of the sample from the processor and transmit the output signal of the system. The hardware integrated into the transmitter may be configured to sample, downconvert, and determine the power level. The sampling, downconverting, and determining may occur external to the transmitter. The transmitter may be further configured to transmit feedback information within a transmission overhead bandwidth of the output signal. The transmitter may be further configured to transmit feedback information using low-speed auxiliary signaling. The downconverting may be such that any portion of or frequency of the signal is sampled by a single filtering and power detection device. A phase of the predistorter may be swept from 0 to 359 degrees.

Aspects and applications of the disclosure presented here are described below in the drawings and detailed description. Unless specifically noted, it is intended that the words and phrases in the specification and the claims be given their plain, ordinary, and accustomed meaning to those of ordinary skill in the applicable arts. The inventor is fully aware that he can be his own lexicographer if desired. The inventor expressly elects, as his own lexicographer, to use only the plain and ordinary meaning of terms in the specification and claims unless they clearly state otherwise and then further, expressly set forth the “special” definition of that term and explain how it differs from the plain and ordinary meaning Absent such clear statements of intent to apply a “special” definition, it is the inventor's intent and desire that the simple, plain and ordinary meaning to the terms be applied to the interpretation of the specification and claims.

The inventor is also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventor is fully informed of the standards and application of the special provisions of pre-AIA 35 U.S.C. §112, ¶6 and post-AIA 35 U.S.C. §112(f). Thus, the use of the words “function,” “means” or “step” in the Description, Drawings, or Claims is not intended to somehow indicate a desire to invoke the special provisions of pre-AIA 35 U.S.C. §112, ¶6 and post-AIA 35 U.S.C. §112(f), to define the invention. To the contrary, if the provisions of pre-AIA 35 U.S.C. §112, ¶6 and post-AIA 35 U.S.C. §112(f) are sought to be invoked to define the claimed disclosure, the claims will specifically and expressly state the exact phrases “means for” or “step for, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of pre-AIA 35 U.S.C. §112, ¶6 and post-AIA 35 U.S.C. §112(f). Moreover, even if the provisions of pre-AIA 35 U.S.C. §112, ¶6 and post-AIA 35 U.S.C. §112(f) are invoked to define the claimed disclosure, it is intended that the disclosure not be limited only to the specific structure, material or acts that are described in the preferred embodiments, but in addition, include any and all structures, materials or acts that perform the claimed function as described in alternative embodiments or forms of the invention, or that are well known present or later-developed, equivalent structures, material or acts for performing the claimed function.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIGS. 1-2 depict prior art systems for waveform digital predistortion according to indirect and direct methods, respectively. FIGS. 2A-3B depicts implementations of methods of frequency estimation as known in the prior art.

FIGS. 3-4 depict prior art systems for data digital predistortion according to indirect and direct methods, respectively.

FIG. 5 is a block diagram of an implementation of a system for waveform predistortion that applies an adaptive algorithm.

FIG. 6 depicts a typical block up-converter as known in the prior art.

FIGS. 7A-B depict implementations of a distortion-power adapted predistorter (DPAPD) microwave band linearizer in a block up converter.

FIGS. 8A-B depict implementations of a DPAPD L-band linearizer in a block up converter.

FIG. 9 is a block diagram of a method of distortion-power adapted predistortion.

FIGS. 10A-B depict implementations of a legacy/stand-alone box configuration for implementing DPAPD in a block up-converter not previously configured with DPAPD hardware.

FIGS. 11A-B depict implementations of a legacy/stand-alone box configuration for implementation DPAPD in a solid state power amplifier not previously configured with DPAPD hardware.

### DESCRIPTION

This disclosure, its aspects and implementations, are not limited to the specific components or methods disclosed herein. Many additional components and assembly procedures known in the art consistent with the intended linearizer reference will become apparent for use with particular implementations from this disclosure. Accordingly, for example, although particular implementations are disclosed, such implementations and implementing components may comprise any components, models, versions, quantities, and/or the like as is known in the art for such systems and implementing components, consistent with the intended operation.

The present disclosure relates to linearizers, particularly for waveform predistortion used in radio frequency(RF) communications and systems which pass a signal through nonlinear devices for any type of processing or alteration such as the transmission of data through the use of high order digital modulation techniques such as Quadrature Amplitude Modulation (QAM) and Phase Shift Keying (PSK). Specifically, particular embodiments of this disclosure relate to the system characterization that most reduces the Adjacent Channel Leakage Ratio (ACLR) or its equivalents, for use in a waveform predistorter. The method through which the values of the polynomial coefficients are solved for and generated affects their magnitude or their ability to reduce the ACLR generated by a band-limited signal passing through a nonlinear device thereby increasing the error performance of high order modulation signals. Advantages that may be achieved through particular embodiments of this disclosure include not only solving for these coefficients in a manner that provides the lowest ACLR achievable in a given system with a waveform predistorter(and doing so in an intuitive manner), but primarily to do so in a low computational footprint by using a method that is not multivariable and that more truly relates to the system inverse of a nonlinear system than that of typical waveform predistortion coefficient generation algorithms such as the least mean square (LMS) algorithm and the batch least square (BLS) algorithm.

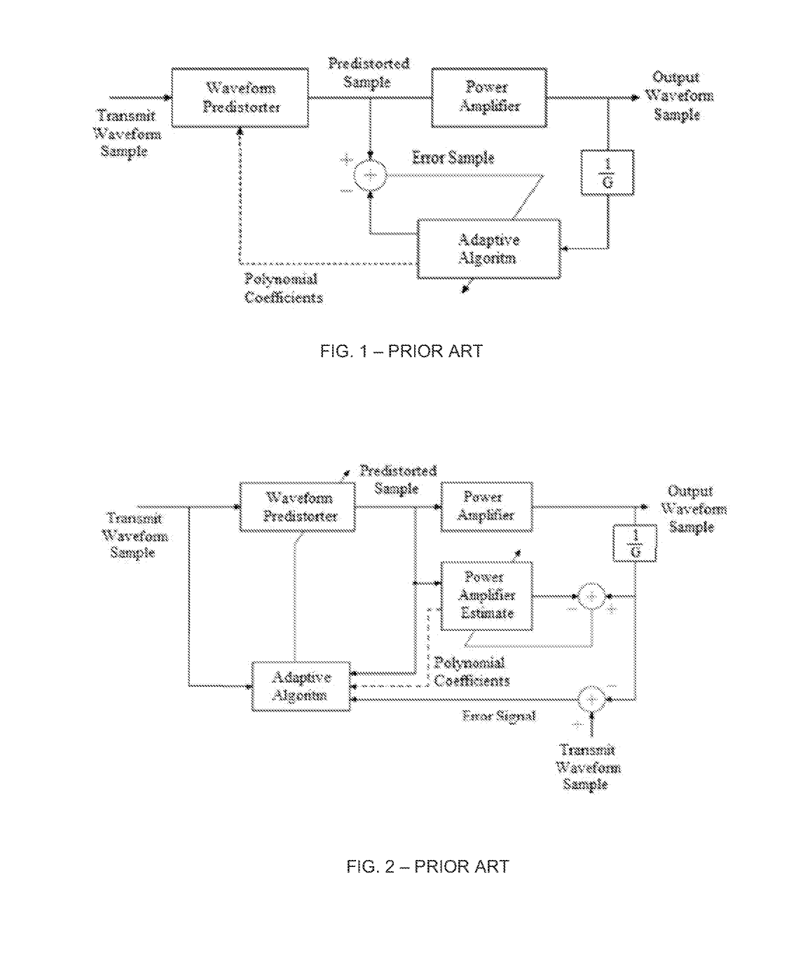

Current techniques for generation of polynomial coefficients for polynomially based predistorters generally fall into two classes: 1) waveform; and 2) data. Waveform predistorters either involve the comparison between a time domain signal that has passed through a transmit filter at the output of the system to which the predistortion is being applied and the same output signal after it is divided by the intended linear gain of the system by way of the LMS or BLS algorithm, or the complex power out over a range of powers in to the system to which the predistortion is being applied by way of the least mean square (LMS) or batch least square (BLS) algorithm using the indirect method as shown in the block diagram of FIG. 1 or a direct method as depicted in FIG. 2.

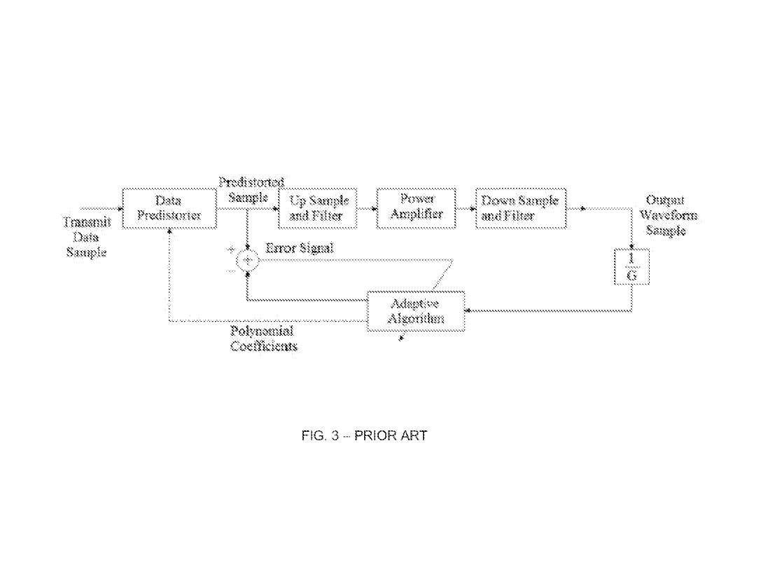

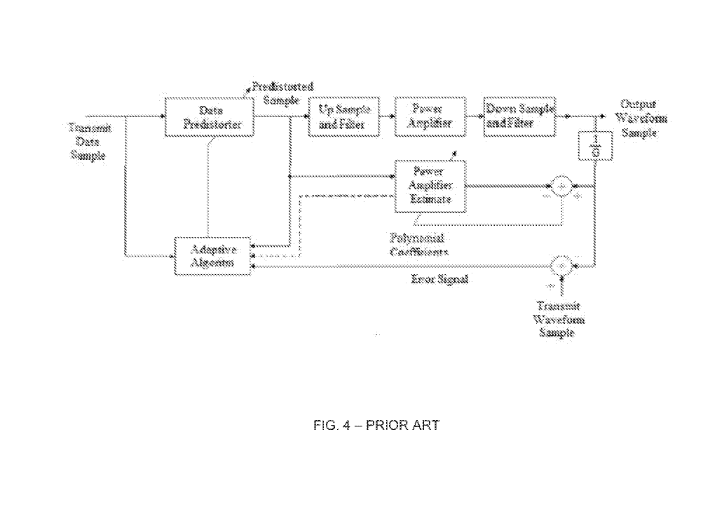

Similarly, a data digital predistorter involves the comparison of a data domain signal, that has not been up-sampled or passed through a transmit filter. The comparison is made between the input to the digital up-sampling that precedes the system to which the predistortion is being applied and the same data domain signal after it passes through the system to which the predistortion is being applied and has been passed through a receive filter and down sampled, through the LMS or BLS algorithm using an indirect method as shown in FIG. 3 or a direct method as shown in FIG. 4.

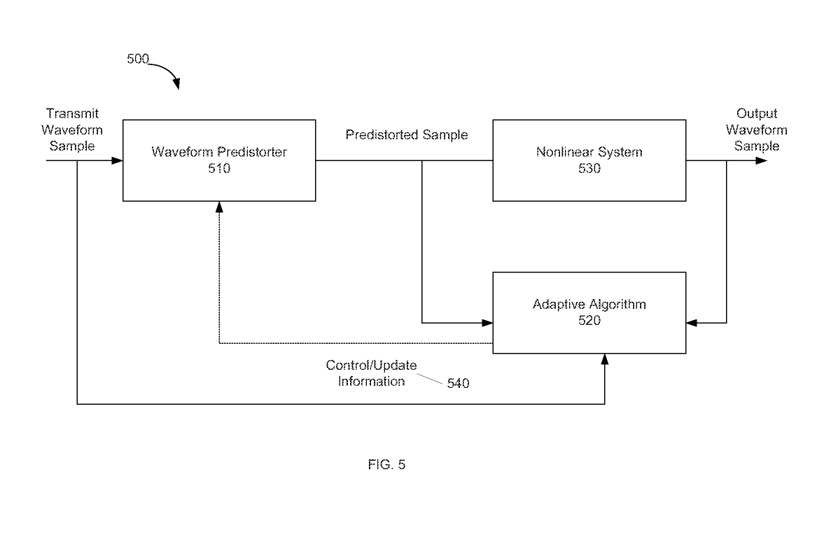

Particular embodiments of the present disclosure have several advantages when compared to conventional methods and systems described above. One such advantage may be that particular embodiments of the disclosed method and system converge toward the lowest ACLR level rather than converging towards the lowest error signal as in the prior art. This convergence may also occur much faster than when using the regular LMS algorithm which also has the disadvantage of only converging to a LMS error result. BLS is usually not practical for implementation in Field Programmable Gate Arrays (FPGA's) as it requires matrix inversion of large matrices which adds cost and complexity. FIG. 5 depicts a block diagram of an implementation of a system for N^{th} order product predistortion coefficient generation (NOPCG) 500 and as shown, comprises a waveform predistorter 510 and the application of an adaptive algorithm 520 that generates control or update information 540 for use in a nonlinear system 530. As depicted here, the power amplifier estimate block has been eliminated, which results in this implementation functioning more closely to the indirect feedback method in terms of complexity while performance is maintained as equal to or greater than that of the direct feedback method thereby resulting in a reduction of complexity, cost, and components.

One aspect of the novelty in this technique used in particular embodiments is the sole utilization of frequency domain information. This is advantageous for at least two reasons. The first is that the frequency domain data can be thought of as the average of a set of time domain data. Since the data is in an average format, it is much less dynamic than time domain data (in terms of large changes in value versus small, slow changes in value) and makes it much easier to converge upon a solution with. This also makes it much better for use with a memory-less polynomial in a system with heavy memory use. Unlike LMS or BLS whose lowest possible mean squared error or least square error will increase as PA memory increases due to the fact that different samples provide contradictory (non-unique) solutions, it is based on an average of data and the frequency domain data contains all the memory information that the time domain signal contains but it is averaged. The second advantage is that the solutions for ACLR are explicit when employing the disclosed methodology. Time domain solutions use a composite signal (the time domain signal output of a nonlinear system is the composite of all the nonlinear signals that exist on the output during the sampling time) and therefore have an inherently difficult time adapting the nonlinear coefficients as their powers are much less than those of the fundamental (desired) signals. Implementations of methods employing an implementation of the NOPCG algorithm do not have this difficulty because coefficients are generated based on a non-composite signal and therefore require a much shorter duration to converge quickly on a strong solution. This is also part of what distinguishes the disclosed methods from frequency domain LMS. Embodiments of the disclosed method are not a LMS algorithm as they do not simultaneously take into account multiple coefficients during generation but rather generate them separately and pseudo-independently. The non-limiting example provided herein shows an example of the specifics for the algorithm; however, the algorithm can be applied for various other combinations of coefficient conditions and with other predistortion equation models (for example, Memory Polynomial model, Volterra Series, Neural Network, Time Delay and Recurrent Time Delay Neural Network, etc.).

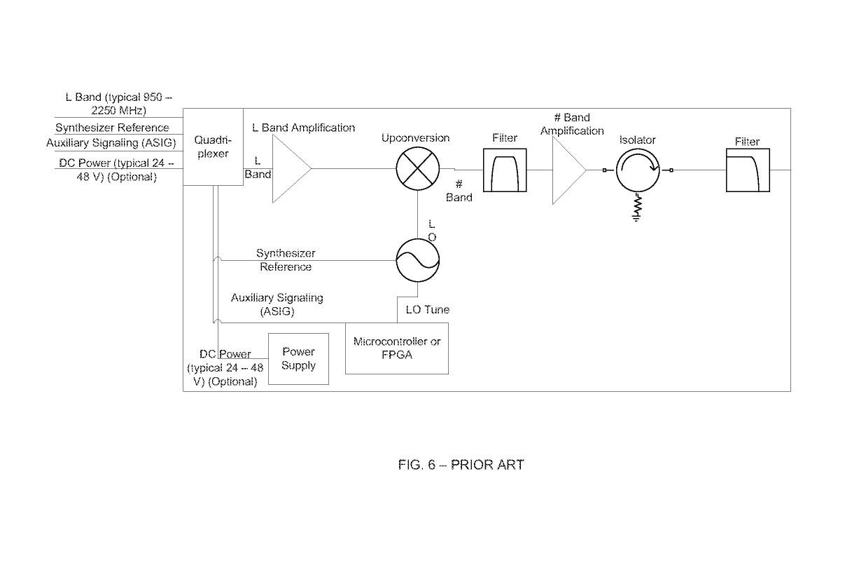

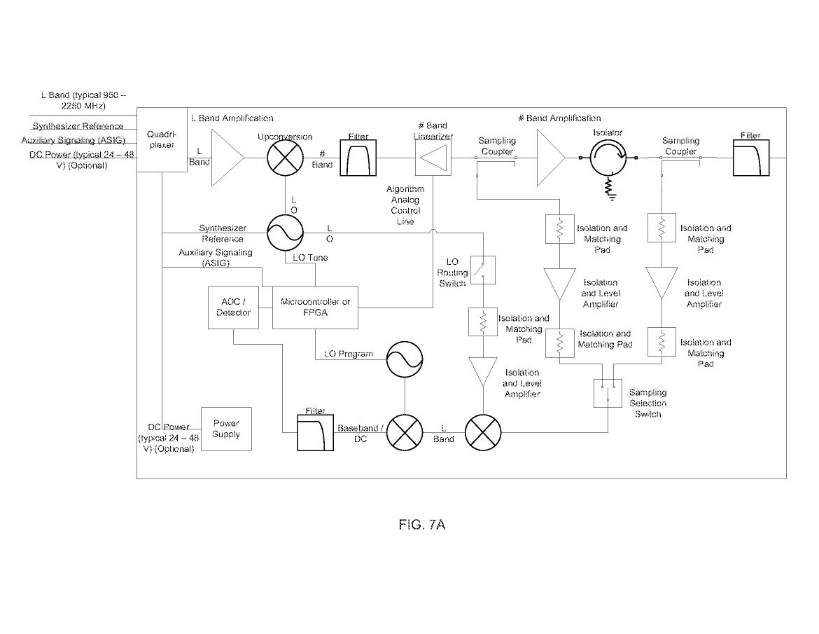

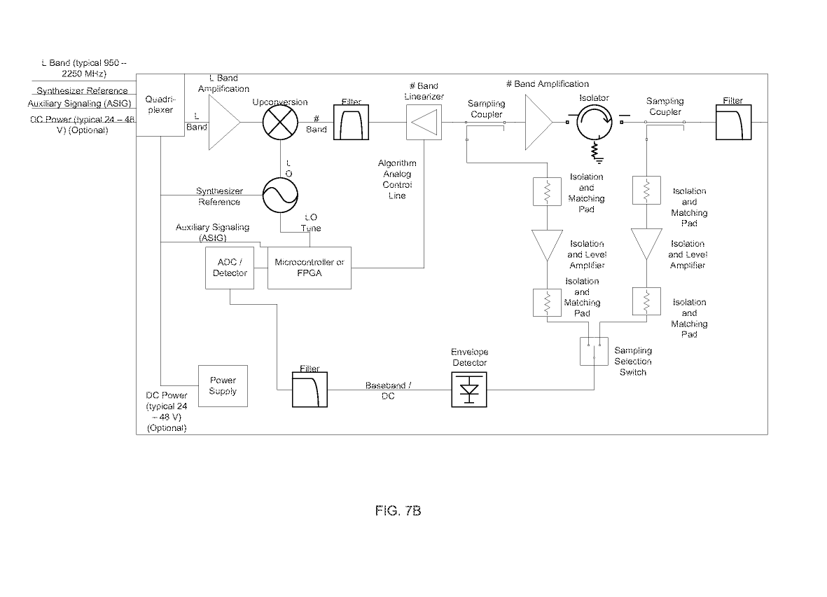

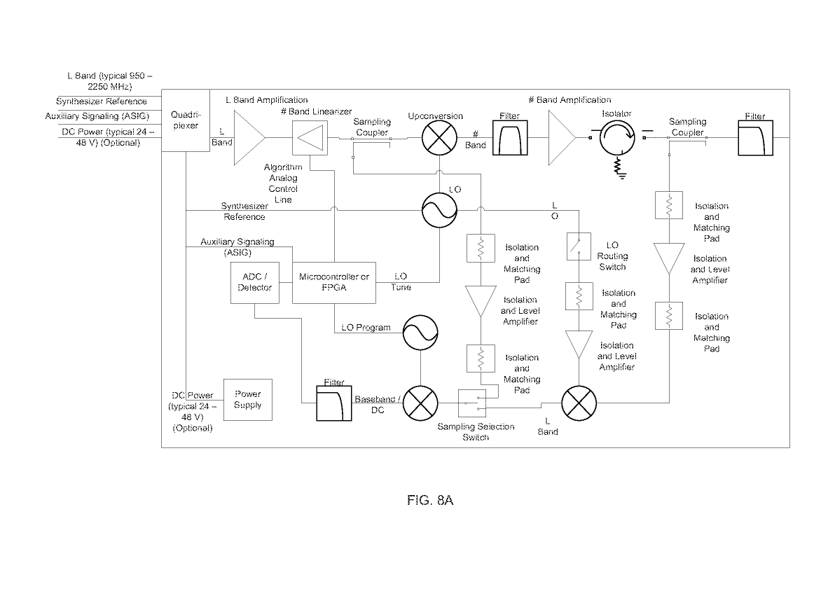

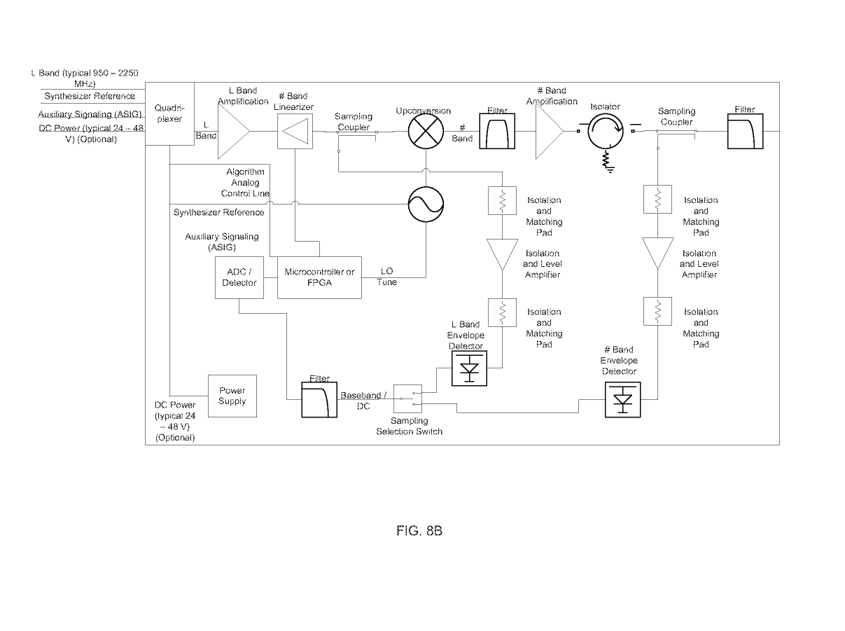

FIG. 6 depicts a typical block up-converter that is not equipped with distortion-power adapted predistorter (DPAPD) functionality. By way of example and not limitation, FIGS. 7A-B and FIGS. 8A-B provide depictions of implementations of system architecture for a DPAPD microwave band linearizer and a DPAPD L-band linearizer respectively. Such implementations reduce the feedback bandwidth such that digital predistortion (DPD) or adaptive analog predistortion (AAPD) may be supported through low speed auxiliary signaling or incorporated into transmission overhead. This is attributed to such DPAPD implementations providing DPD and AAPD algorithms that are designed for systems requiring narrowband, slow, and/or minimal feedback information as well as the necessary hardware to obtain such feedback information. Such implementations also allow for narrowband, slow, and/or minimal feedback information to be exchanged between transmitter equipment such as for example, microwave transmitter equipment, and transmitter processing equipment as well as between receiver and transmitter processing equipment.

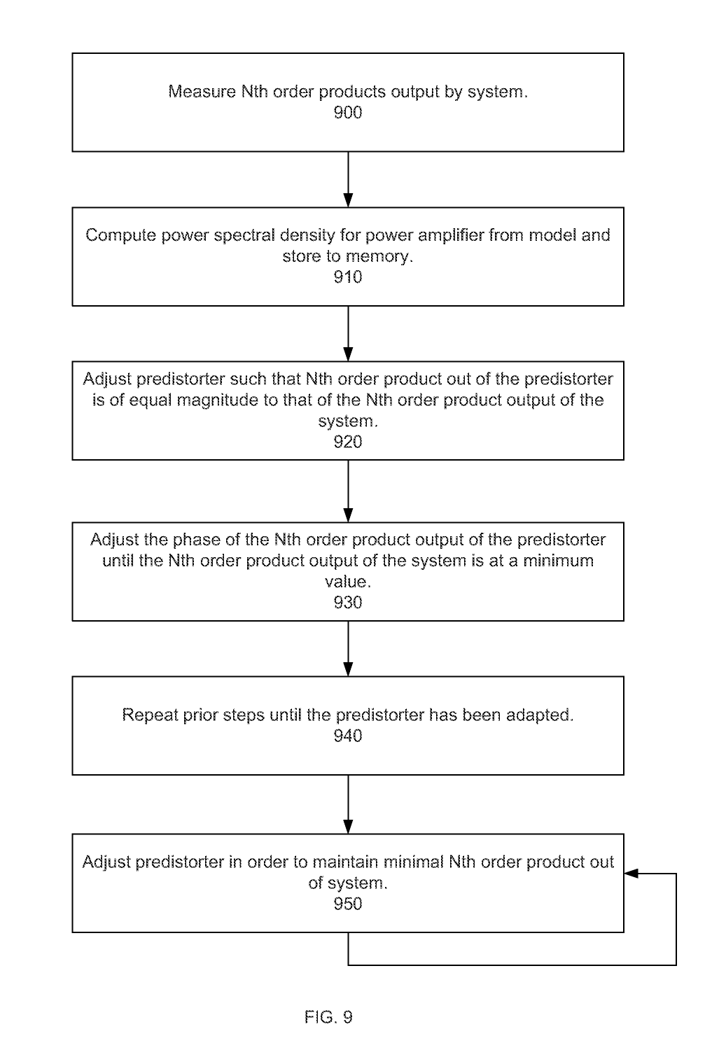

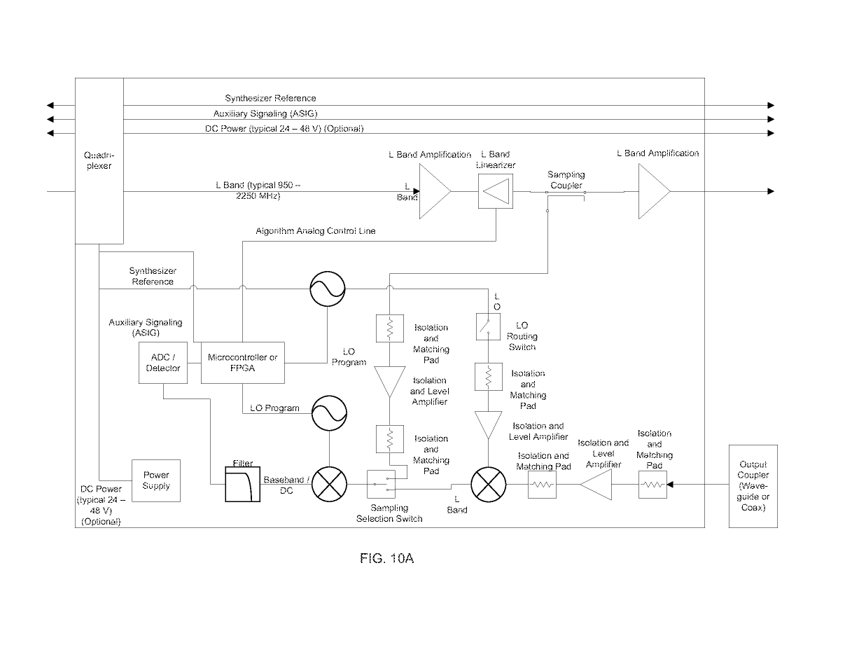

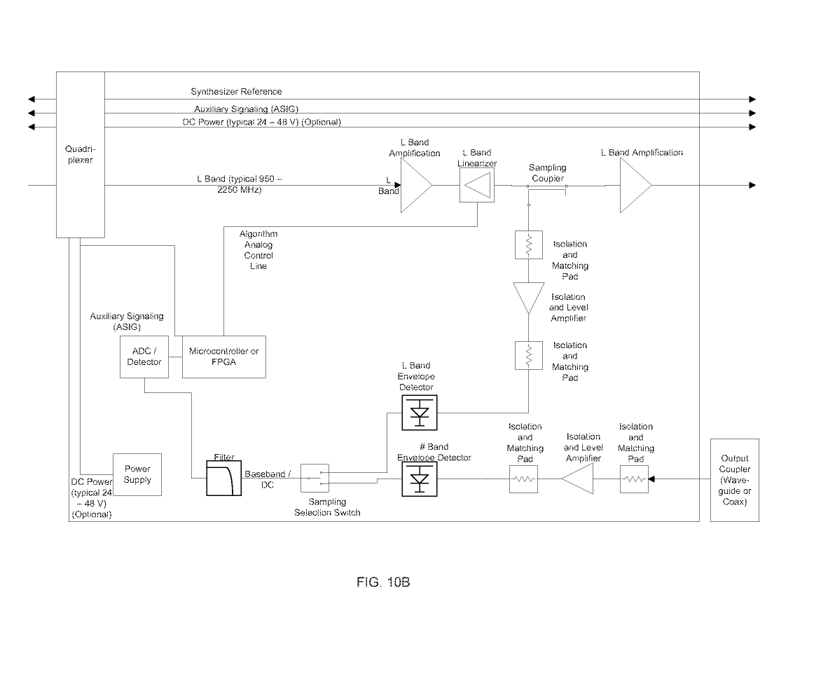

Implementations of DPAPD systems and methods may allow DPD and/or AAPD to be implemented such that local and/or remote adaptation may be achieved without limiting interoperability of the related equipment. As shown in FIG. 9, implementations of the disclosed method may use a frequency domain-based adaptation algorithm that comprises measuring the N^{th} order products from the output of a system such as for example, a system comprising microwave equipment 900 and computing the power spectral density for the power amplifier (for example, using a model) and storing this value in a memory 910. One predistorter coefficient at a time is then adjusted such that the N^{th} order product out of the predistorter is of equal magnitude relative to the carrier signal to the N^{th} order product of the output signal of the microwave equipment 920, which may be accomplished in some implementations by 1) setting all non-linear predistorter coefficients=0 and coefficients generated=0; 2) setting the active coefficient of the predistorter to the (max_order−(2*coefficients_generated)) coefficient; and 3) setting the predistorter active coefficient magnitude to that of the power amplifier model coefficient magnitude of the same order as max_order−coefficients_generated. The phase of the N^{th} order product of the predistorter may be adjusted until the N^{th} order product of the output of the microwave equipment is at a minimum value 930, which may be accomplished by setting the predistorter active coefficient phase to 180 degrees less than that of the power amplifier model coefficient of the same order to max_order−coefficients_generated. The coefficients may be iteratively adjusted by incrementing coefficients_generated and these steps may be repeated until all of the predistorters coefficients have been adapted 940, at which point coefficients_generated=max_order. The predistorter may then continue to be adjusted such that the minimal N^{th} order product output of the system is maintained 950.

Alternatively, one predistorter coefficient at a time may be adjusted such that the N^{th} order product of the output signal of the microwave equipment is at a minimum by 1) setting all non-linear predistorter coefficients=0 and coefficients_generated=0; 2) setting the active coefficient of the predistorter to the (max_order−(2* coefficients_generated)) coefficient; and 3) incrementing the predistorter active coefficient magnitude and phase until computed power spectral density of the power amplifier at (max_order−(2*coefficients generated)) symbol rates away from the center of the channel and is at a minimum. The predistorter active coefficient phase may be swept within a range, for example, from 0 to 359 degrees and the best results of the sweep may then be applied. The coefficients may then be iteratively adjusted by incrementing coefficients_generated and these steps may be repeated until all of the predistorters coefficients have been adapted, at which point coefficients_generated=max_order. In some implementations, the coefficients that are solved for will be applied to the waveform predistorter through the use of analog control lines.

While exemplary implementations of system architecture for use in carrying out the DPAPD methods are provided in the accompanying figures, these implementations are intended as examples only and implementations of such systems are not intended to be limited to the these specific hardware components or configurations. In some implementation, the associated feedback hardware is configured to obtain a signal sample as dictated by the implementations of the methods described above, of the signal on which the predistortion is to be performed. This sample may be isolated from the received signal so as to prevent processing noise from corrupting the received signal. A downconverter may be used to downconvert the sample so that any portion of or frequency in the desired received signal may be sampled using a single filtering and power distribution mechanism to enhance efficiency. Implementations of the system may also be equipped to measure the power level of the sample and/or use available low speed auxiliary signaling or transmission overhead to feed the sampled power level to the transmission processing equipment.

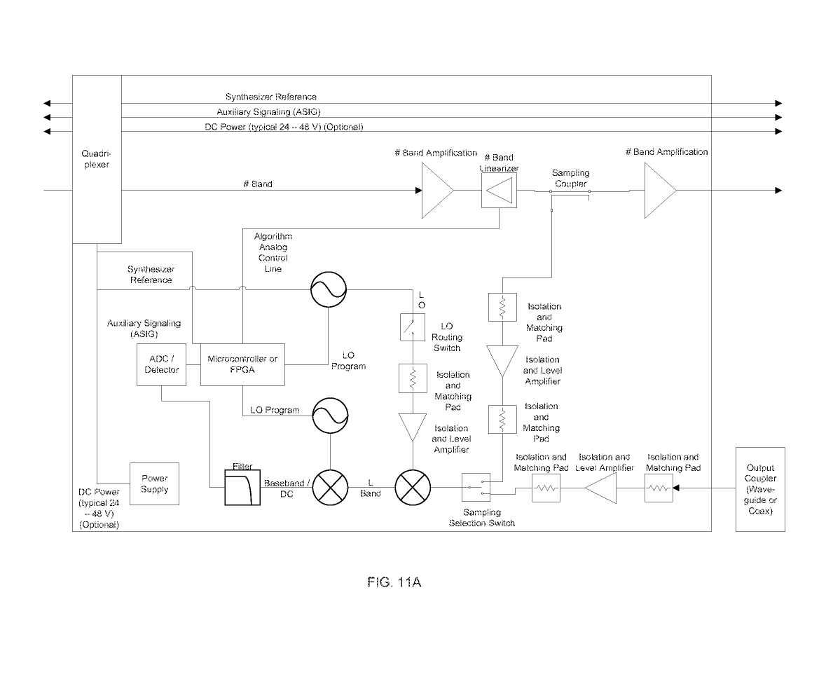

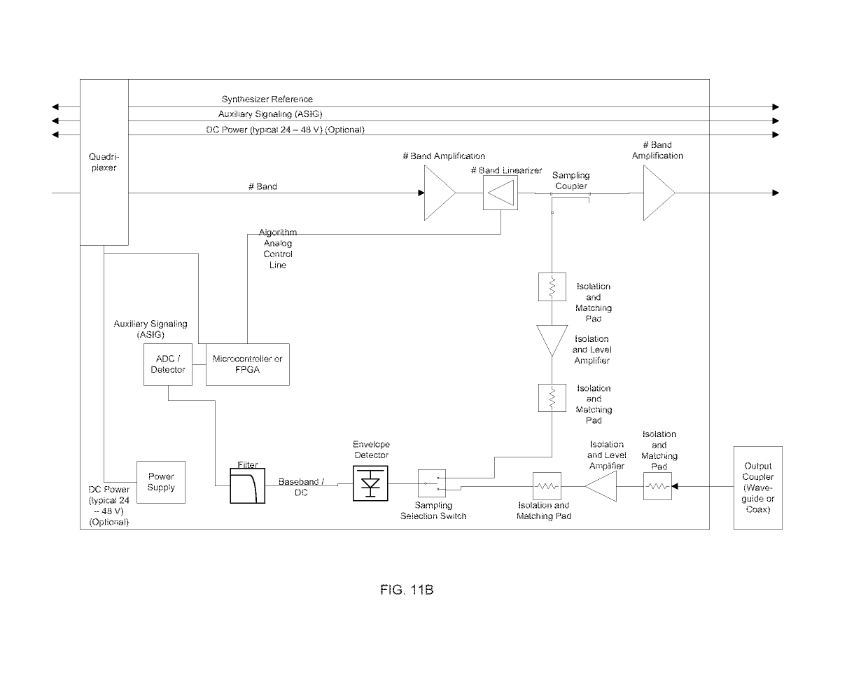

Implementations of a system for DPAPD may be configured such that the feedback hardware is integrated into the transmission equipment, such as for example, in transmitter microwave equipment as shown in FIGS. 7A-8B, or alternatively, may be external to the transmission equipment as shown in FIGS. 10A-11B. Specifically, FIGS. 10A-B depict examples of a legacy box/stand-alone architecture which may be used to implement DPAPD methodology in existing equipment that does not contain the appropriate hardware to implement DPAPD directly within the existing equipment. FIGS. 11A-B depict an examples of a legacy box/stand-alone architecture that may be used with solid state power amplifiers in which the interface is at microwave frequencies.

Embodiments of DPAPD systems and methods may utilize components such as a Field Programmable Gate Array (FPGA), microcontroller, or any other suitable processor for performing implementations of the disclosed methods. Alternatively, these methods may also be implemented through the use of semiconductors such as diodes, FETs, or even a linear system that has sufficient bandwidth to mimic a non-linear system. For a semiconductor implementation, the semiconductor may be characterized similarly to a power amplifier and then biased such that at the bias point, its polynomial most closely matches that of the coefficient generated by the N^{th} order product predistortion coefficient generator. This may or may not require a cascade of multiple diodes in order to arrive at the desired polynomial. The first diode in the cascade may be used to set the highest order coefficient as this is the diode that will see the highest input power and therefore be most nonlinear. After the signal passes through the first diode and therefore will incite a more linear response from the second diode, meaning that the second diode may be used to set the lower order coefficients and correct for the lower order coefficient information added by the first diode. The same may also be true for the second and third diodes as well as through the (n−1)^{th} and n^{th} diode until the power level is in the linear operation region of the (n+1)^{th} diode.

Implementations of the disclosed system and methods may provide the advantage of interoperability among equipment made by various manufacturers and of varying ages as the processing power may be placed external to the microwave equipment so that it may integrate with legacy systems while still maintaining a standard system interface. Previously, the use of very low speed feed-forward signals in conjunction with very low speed feedback with AAPD external to the processing equipment and the application of AAPD to communication systems comprised of equipment from various manufacturers was not possible. Implementations of the disclosed system and methods may also provide the ability of having processing equipment-controlled predistortion originating from multiple processing equipment components.

It will be understood that embodiments and implementations described and illustrated herein are not limited to the specific components disclosed herein, as virtually any components consistent with the intended operation of a method and/or system implementation for redundancy protection may be utilized. In places where the description above refers to particular embodiments of a communications system or redundancy protections techniques, it should be readily apparent that a number of modifications may be made without departing from the spirit thereof and that these implementations may be applied to other communications systems and components. The presently disclosed implementations are, therefore, to be considered in all respects as illustrative and not restrictive.

The implementations listed here, and many others, will become readily apparent from this disclosure. From this, those of ordinary skill in the art will readily understand the versatility with which this disclosure may be applied.

1. A method of generating N^{th} order product predistortion coefficients for use by a linearizer in a non-linear communications system comprising:
receiving an input signal by a processor;
applying, by the processor, a frequency domain-based adaptation algorithm by:
measuring N^{th} order products of an output signal of the system; and
iteratively adjusting a predistortion coefficient of a predistorter until an N^{th} order product output of the processor is substantially equal to a predetermined value.

2. The method of claim 1, further comprising iteratively adjusting a phase of the predistorter until the N^{th} order product output of the system is substantially equal to a predetermined minimum value.

3. The method of claim 1, wherein the predetermined value is substantially equal to an N^{th} order product output of the system.

4. The method of claim 1, further comprising:
sampling and isolating the input signal prior to predistortion using the processor;
downconverting the sample using a downconverter;
determining a power level of the sample; and
transmitting the power level of the sample to a transmitter.

5. The method of claim 4, wherein the sampling, downconverting, and determining occurs within hardware integrated into the transmitter.

6. The method of claim 4, wherein the sampling, downconverting, and determining occurs external to the transmitter.

7. The method of claim 4, further comprising transmitting feedback information within a transmission overhead bandwidth of the output signal.

8. The method of claim 4, further comprising transmitting feedback information using low-speed auxiliary signaling.

9. The method of claim 4, wherein the downconverting is such that any portion of or frequency of the signal is sampled by a single filtering and power detection device.

10. The method of claim 1, further comprising sweeping a phase of the predistorter from 0 to 359 degrees.

11. A system for generating N^{th} order product predistortion coefficients for use by a linearizer in a non-linear communications system comprising:
a processor configured to:
receive an input signal; and
apply a frequency domain-based adaptation algorithm by measuring N^{th} order products of an output signal of the system and iteratively adjusting a predistortion coefficient of a predistorter until an N^{th} order product output of the processor is substantially equal to a predetermined value.

12. The system of claim 11, wherein the processor is further configured to iteratively adjust a phase of the predistorter until the N^{th} order product output of the system is substantially equal to a predetermined minimum value.

13. The system of claim 12, wherein the predetermined value is substantially equal to an N^{th} order product output of the system.

14. The system of claim 11, wherein the processor is further configured to sample and isolate the input signal prior to predistortion and determine a power level of the sample and the system further comprises:
a downconverter configured to downconvert the sample; and
a transmitter configured to receive the power level of the sample from the processor and transmit the output signal of the system.

15. The system of claim 14, wherein hardware integrated into the transmitter is configured to sample, downconvert, and determine the power level.

16. The system of claim 14, wherein the sampling, downconverting, and determining occurs external to the transmitter.

17. The system of claim 14, wherein the transmitter is further configured to transmit feedback information within a transmission overhead bandwidth of the output signal.

18. The system of claim 14, wherein the transmitter is further configured to transmit feedback information using low-speed auxiliary signaling.

19. The system of claim 14, wherein the downconverting is such that any portion of or frequency of the signal is sampled by a single filtering and power detection device.

20. The system of claim 11, wherein a phase of the predistorter is swept from 0 to 359 degrees.
